(19) United States
(12) Patent Application Publication
(10) Pub. No.: US 2019/0044452 A1
(43) Pub. Date: Feb. 7, 2019

(54) POWER SUPPLY, LAMP, MOVABLE DEVICE, AND METHOD FOR MANUFACTURING POWER SUPPLY

(71) Applicant: PANASONIC INTELLECTUAL PROPERTY MANAGEMENT CO., LTD., Osaka (JP)

(72) Inventors: Kosaku ARITA, Niigata (JP); Takashi KAMBARA, Osaka (JP)

(73) Assignee: PANASONIC INTELLECTUAL PROPERTY MANAGEMENT CO., LTD., Osaka (JP)

(21) Appl. No.: 16/050,627

(22) Filed: Jul. 31, 2018

(30) Foreign Application Priority Data
Aug. 3, 2017 (JP) 2017-150477

(51) Int. Cl. H02M 7/00; H05K 7/20; H05K 5/02; H05K 5/04; H02M 1/32

(52) U.S. Cl. CPC H02M 7/003; H05K 7/2039; H02M 1/32; H05K 5/04; H05K 5/0213

(57) ABSTRACT

A power supply includes a casing including a heat-conducting material and having an inner surface and an outer surface. The casing is a one-piece component having a substantially tubular shape. The power supply also includes a circuit board disposed in the casing. The circuit board has a first surface on which one or more circuit components are mounted and a second surface on an opposing side of the first surface. The power supply also includes a first cover disposed over a first opening at a first end portion of the casing on a tubular axis, and a second cover disposed over a second opening at a second end portion of the casing on the tubular axis. The first surface of the circuit board faces the inner surface of the casing.

### CROSS REFERENCE TO RELATED APPLICATION

This application claims the benefit of priority of Japanese Patent Application Number 2017-150477 filed on Aug. 3, 2017, the entire content of which is hereby incorporated by reference.

### BACKGROUND

### 1. Technical Field

The present disclosure relates to a power supply, a lamp which includes the power supply, a movable device which includes the lamp, and a method for manufacturing the power supply, and relates in particular to, for instance, a power supply for causing a lamp included in a vehicle to emit light.

### 2. Description of the Related Art

High-intensity discharge lamps and light emitting diodes (LEDs) are used as light sources for lamps such as headlights and taillights of vehicles. A light source in a headlight is disposed in a housing, and emits light using lighting power supplied from a power supply. The power supply of this kind generates lighting power, using a battery carried in a vehicle as a power source.

A conventional power supply includes a metal casing and a circuit board housed in the casing. A plurality of circuit components for causing a light source to emit light are mounted on the circuit board. The casing for housing the circuit board includes two components, namely, for example, a box-shaped case, and a cover for covering an opening of the case (Japanese Unexamined Patent Application Publication No. 2014-086211).

### SUMMARY

When the power supply operates to supply power to the light source, heat is generated from circuit components such as a transistor and a coil component. Accordingly, there has been a demand for the power supply to have heat dissipating capability in order to dissipate heat generated by the circuit components.

As disclosed in Japanese Unexamined Patent Application Publication No. 2014-086211, a conventional power supply is often disposed outside of a housing of a lamp, and is typically water-resistant.

In recent years, there has been a demand for reduction in cost of a power supply, along with an increase in demand for reduction in cost of a lamp assembly. This has led to examinations to make a power supply non water-resistant by disposing the power supply inside of a housing (inside of a lamp).

The temperature in the housing goes high due to light emitted by a light source, and thus there has been a demand for the power supply disposed in the housing to have qualities (such as luminous flux and a life) to withstand use in a higher temperature atmosphere than the conventional power supply. Accordingly, even a heat-generating component may be damaged by overheating if the temperature inside the housing goes high.

Conceivable measures against, heat generated by such a power supply include: adding a control circuit which reduces light output by a light source according to a rise in heat inside of a housing; adding an electric fan for forced cooling; and employing a case inappropriately large for the size of a circuit board, for instance.

However, if light output of a light source is reduced according to a rise in temperature, a user may feel that the brightness of light from a lamp such as a headlight is low. Furthermore, if such a control circuit is added, an electrically driven fan is added, or a large case is employed, not only cost is increased, but also the sizes of the power supply and the lamp are increased.

Ingress of rain water or dew condensation water, for instance, into a housing is inevitable. Accordingly, even a non water-resistant power supply needs to have water resistance to some extent, in order to prevent circuit components, for instance, from being damaged due to ingress of water to the inside.

The present disclosure has been conceived in order to address such problems, and provides, for instance, a power supply having excellent heat dissipating capability and water resistance, without increasing the size of the power supply.

In order to provide such a power supply, a power supply according to an aspect of the present disclosure includes: a casing including a heat-conducting material and having an inner surface and an outer surface, the casing being one-piece component having a substantially tubular shape; a circuit board disposed in the casing, the circuit board having a first surface on which one or more circuit components are mounted and a second surface on an opposing side of the first surface; a first cover disposed over a first opening at a first end portion of the casing on a tubular axis; and a second cover disposed over a second opening at a second end portion of the casing on the tubular axis, wherein the first surface of the circuit board faces the inner surface of the casing.

A lamp according to an aspect of the present disclosure includes: a housing; a light source disposed inside of the housing; and the power supply configured to supply power to the light source, and disposed inside of the housing.

A movable device according to an aspect of the present disclosure includes the lamp.

A method for manufacturing a power supply according to an aspect of the present disclosure includes: forming a casing having a substantially tubular shape by extruding a metallic material, the casing being formed to have a first opening and a second opening; inserting, in a sliding manner, a circuit board into the casing via one of the first opening and the second opening of the casing, the circuit board having a first surface on which one or more circuit components are mounted and a second surface on an opposing side of the first surface; attaching a first cover over the first opening; and attaching a second cover over the second opening, wherein when the circuit board is inserted into the casing, the circuit board is inserted with the first surface facing downward.

According to the present disclosure, a power supply having excellent heat dissipating capability and water resistance, for instance, can be achieved without increasing the size of the power supply.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a perspective view when a power supply according to Embodiment 1 is obliquely viewed from above;

FIG. 2 is a perspective view when the power supply according to Embodiment 1 is obliquely viewed from below;

FIG. 3 is an exploded perspective view of the power supply according to Embodiment 1;

FIG. 4 is a cross-sectional view of the power supply according to Embodiment 1 taken along line IV-IV in FIG. 1;

FIG. 5 is a cross-sectional view of the power supply according to Embodiment 1 taken along line V-V in FIG. 4;

FIG. 6 is a cross-sectional view of the power supply according to Embodiment 1 taken along line VI-VI in FIG. 4;

FIG. 7 is a diagram illustrating examples of steps of producing a casing included in the power supply according to Embodiment 1;

FIG. 8 is a diagram illustrating a method for manufacturing the power supply according to Embodiment 1;

FIG. 9 is a cross-sectional view when a circuit board is slid, in the method for manufacturing the power supply according to Embodiment 1;

FIG. 10 is a cross-sectional view of the casing in which the circuit board is disposed when the casing is turned upside down, in the method for manufacturing the power supply according to Embodiment 1;

FIG. 11 illustrates a state when a power supply is attached to a housing of a lamp according to Embodiment 2;

FIG. 12 is a perspective view illustrating a state when the power supply is disposed in the housing of the lamp according to Embodiment 2;

FIG. 13 is a front view illustrating a state when the power supply is disposed in the housing of the lamp according to Embodiment 2;

FIG. 14 is a front view of a vehicle according to Embodiment 3;

FIG. 15 is a partially enlarged cross-sectional view of a power supply according to Variation 1;

FIG. 16 is a cross-sectional view of a power supply according to Variation 2;

FIG. 17 is a perspective view of a power supply according to Variation 3;

FIG. 18 is a perspective view of a lamp and a power supply according to Variation 4;

FIG. 19 is a perspective view of a power supply according to Variation 5;

FIG. 20 is a front view of a lamp according to Variation 5;

FIG. 21 is a perspective view of a power supply according to Variation 6;

FIG. 22 is a front view of a lamp according to Variation 6;

FIG. 23 is a perspective view of a power supply according to Variation 7;

FIG. 24 is a front view of a lamp according to Variation 7;

FIG. 25 is a perspective view of a power supply according to Variation 8;

FIG. 26 is a front view of a lamp according to Variation 8;

FIG. 27 is a perspective view illustrating a state where a first cover of a power supply according to Variation 9 is removed;

FIG. 28 is a perspective view of a lamp according to Variation 9 (a perspective view illustrating a state where the first cover of the power supply is removed); and

FIG. 29 is a perspective view of the power supply according to Variation 10.

### DETAILED DESCRIPTION OF THE EMBODIMENTS

The following describes embodiments of the present disclosure with reference to the drawings. Note that the embodiments described below each show a specific example of the present disclosure. Thus, the numerical values, shapes, materials, elements, the arrangement and connection of the elements, steps, and the processing order of the steps, for instance, shown in the following embodiments are mere examples, and thus are not intended, to limit the present disclosure. Therefore, among the elements in the embodiments below, elements not recited in any of the independent claims defining the broadest concept of the present disclosure are described as arbitrary elements.

The drawings are schematic diagrams, and do not necessarily provide strict illustration. Note that in the drawings, the same numeral is given to a substantially same configuration, and a redundant description thereof may be omitted or simplified.

In the specification and the drawings, the X axis, the Y axis, and the Z axis represent three axes of a three-dimensional orthogonal coordinate system. In the embodiments, the Z-axis direction is a vertical direction, and a direction perpendicular to the Z axis (a direction parallel to the X-Y plane) is a horizontal direction. The X axis and the Y axis are orthogonal to each other, and are both orthogonal to the Z axis.

### Embodiment 1

### Configuration

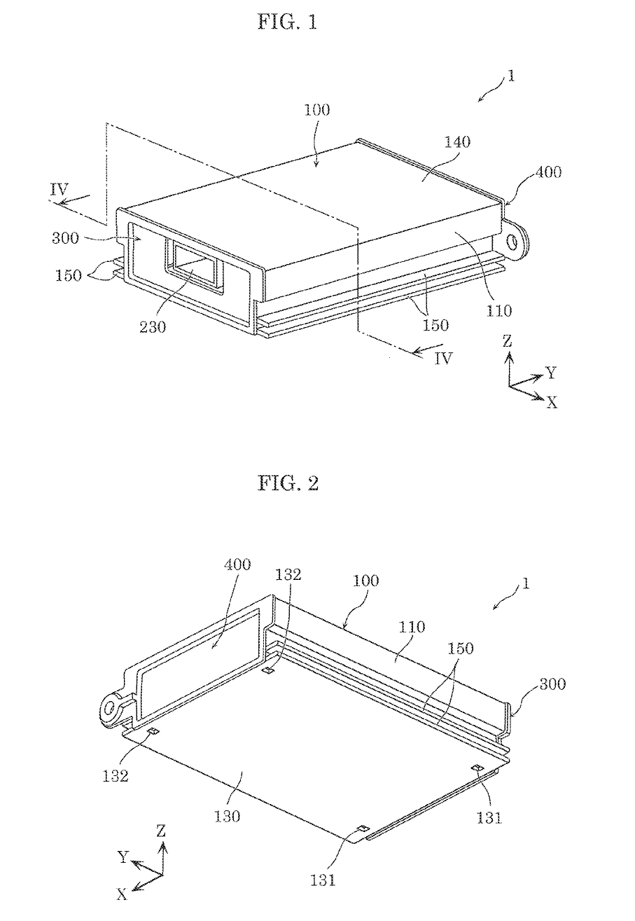

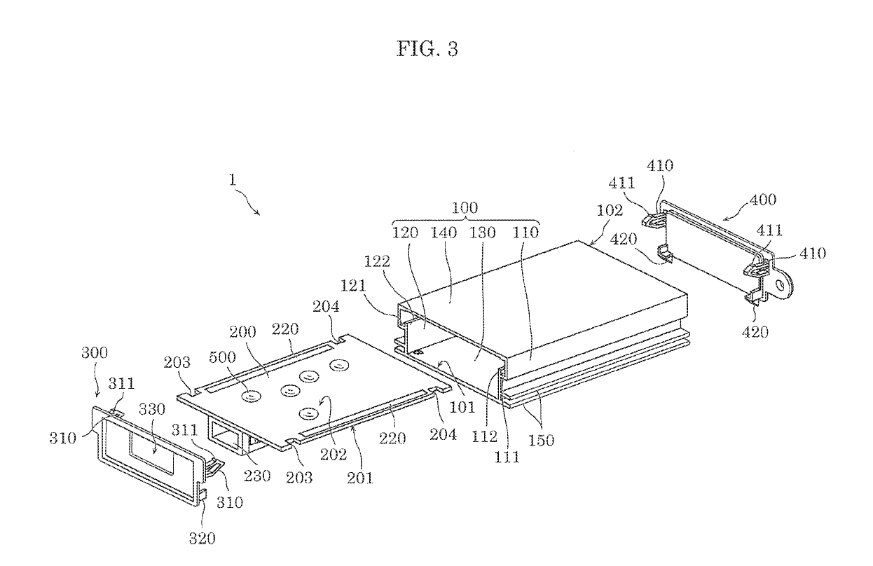

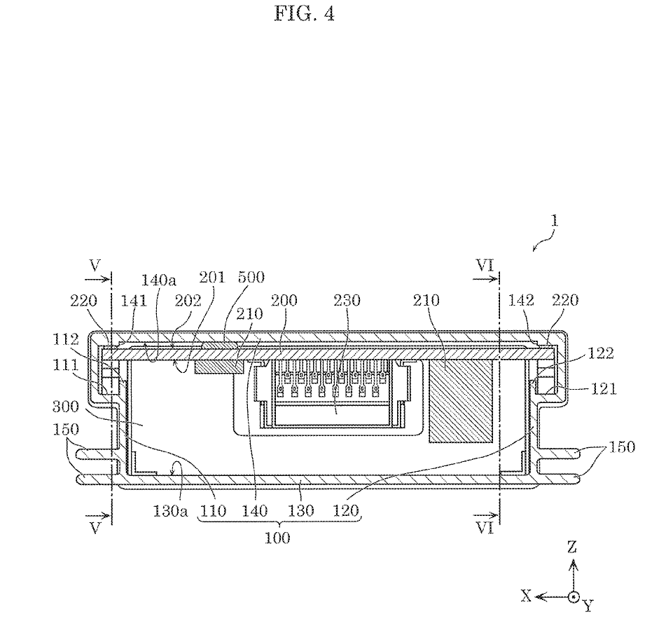

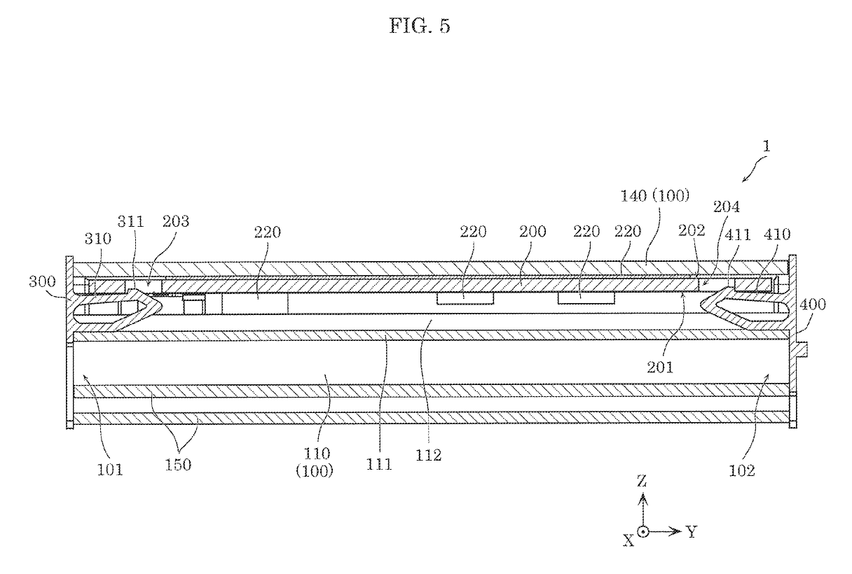

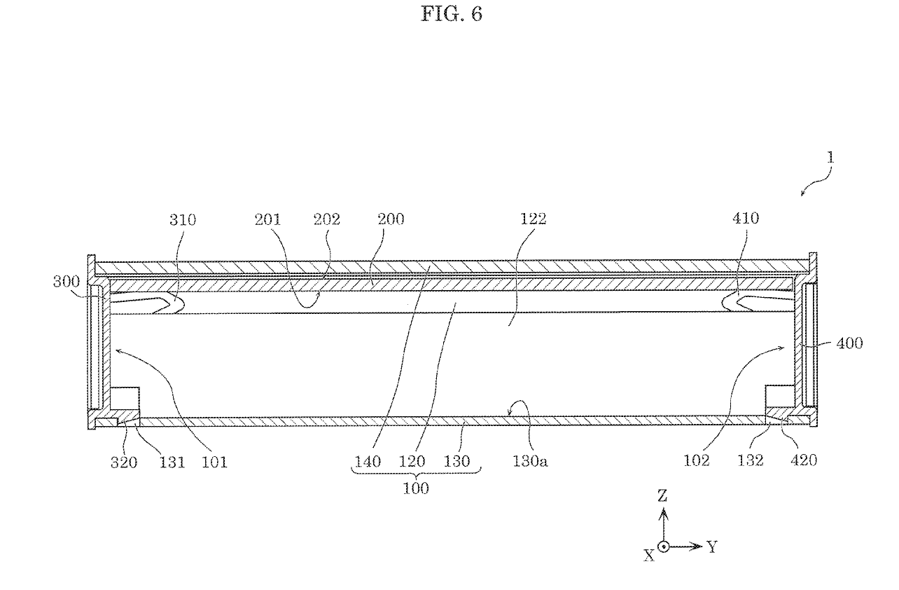

The following describes a configuration of power supply 1 according to Embodiment 1 with reference to FIGS. 1 to 6. FIG. 1 is a perspective view when power supply 1 according to Embodiment 1 is obliquely viewed from above. FIG. 2 is a perspective view when power supply 1 as illustrated in FIG. 1 is obliquely viewed from below. FIG. 3 is an exploded perspective view of power supply 1 as illustrated in FIG. 1. FIG. 4 is a cross-sectional view of power supply 1 as illustrated in FIG. 1 taken along line IV-IV in FIG. 1. FIG. 5 is a cross-sectional view of power supply 1 as illustrated in FIG. 1 taken along line in FIG. 4, and FIG. 6 is a cross-sectional view of power supply 1 as illustrated in FIG. 1 taken along line VI-VI in FIG. 4.

Power supply 1 is a light-emitting diode (LED) lighting drive circuit module for causing LEDs to emit light, which are used as, for example, light sources of a headlight of a vehicle. Power supply 1 as illustrated in FIGS. 1 to 6 includes casing 100 having a space inside, circuit board 200 disposed inside of casing 100, first cover 300, second cover 400, and heat conduction member 500.

Casing 100 is a case body which houses circuit board 200. Casing 100 includes a heat-conducting material, and functions as a beat sink for dissipating heat generated by circuit components 210 mounted on circuit board 200. Accordingly, the outer surface of casing 100 may account for at least 80% of the total outer surface area of power supply 1.

For example, a metallic material or a highly heat-conducting resin material having a heat conductivity of 5 W/(mK) may be used as the heat-conducting material included in casing 100. Casing 100 is made of a metallic material in the present embodiment. Specifically, casing 100 is an extruded aluminum casing. As an example, casing 100 is A6063S-5T which is uncoated. In addition, an example of the thickness of casing 100 is in a range from 1.0 mm to 1.5 mm, but the thickness is not limited to this range.

Note that if a highly heat-conducting resin material is used as the heat-conducting material of casing 100, the heat-conducting material may have not only heat conductivity, but also electrical conductivity. In this case, a material obtained by, for example, including in a base resin carbon fiber, graphite, metal filler, or inorganic filler, for instance, may be used as the heat-conducting material of casing 100. This achieves reduction in the weight and cost of casing 100.

Casing 100 is a substantially tubular one-piece component having openings on both end portions. Specifically, casing 100 is an integrally formed component with no circumferential breaks (cut portions) in an arbitrary cross section normal to a tubular axis (Y axis).

Casing 100 has first opening 101 provided at an end portion of casing 100 on the tubular axis, and second opening 102 provided at another end portion of casing 100 on the tubular axis. Circuit board 200 is slidingly inserted into casing 100 from one of first opening 101 and second opening 102 of casing 100, whereby circuit board 200 can be housed in casing 100. Thus, circuit board 200 housed in casing 100 is mechanically protected by casing 100.

As illustrated in FIGS. 1 to 3, casing 100 in the present embodiment has a thin box shape as a whole, and includes first side wall 110, second side wall 120, bottom plate 130, and top plate 140. Specifically, casing 100 includes first side wall 110, second side wall 120, bottom plate 130, and top plate 140 as an outer enclosure, and first side wall 110, second side wall 120, bottom plate 130, and top plate 140 surround four lateral surfaces about the tubular axis.

First side wall 110 is located at an end portion of circuit board 200 in a direction (the X-axis direction in the present embodiment) orthogonal to the sliding direction in which circuit board 200 is slidingly inserted into casing 100. On the other hand, second side wall 120 is located at another end portion of circuit board 200 in the direction orthogonal to the sliding direction of circuit board 200. Specifically, second side wall 120 is present in a position opposite first side wall 110. Note that the sliding direction of circuit board 200 in the present embodiment is the Y-axis direction.

First side wall step portion 111 is formed on first side wall 110. First side wall step portion 111 is formed into a step shape such that a portion of first side wall 110 near top plate 140 projects outward. Similarly, second side wall step portion 121 is formed on second side wall 120. Second side wall step portion 121 is formed into a step shape such that a portion of second side wall 120 near top plate 140 projects outward. Second side wall step portion 121 has a shape bilaterally symmetrical to first side wall step portion 111.

Widthwise end portions of circuit board 200 (end portions of circuit board 200 on the X axis in the present embodiment) are placed on the projection on first side wall 110 formed by first side wall step portion 111 and the projection on second side wall 120 formed by second side wall step portion 121. The internal surface of the projection on first side wall 110 and the internal surface of the projection on second side wall 120 function as positioning portions which determine the widthwise position of circuit board 200, and also function as guide surfaces which restrict the widthwise end portions of circuit board 200 (i.e., end portions in the direction crossing the sliding direction) when circuit board 200 is slidingly inserted into casing 100.

First rib 112 protruding from first side wall step portion 111 towards first surface 201 of circuit board 200 is disposed on first side wall 110. Similarly, second rib 122 protruding from second side wall step portion 121 towards first surface 201 of circuit board 200 is disposed on second side wall 120.

First rib 112 and second rib 122 function as supporting portions which support; circuit board 200 when circuit board 200 is slidingly inserted into casing 100.

First rib 112 and second rib 122 are each formed into a plate, and extend along the tubular axis of casing 100. A spacing between first rib 112 and first surface 201 of circuit board 200 and a spacing between second rib 122 and first surface 201 of circuit board 200 are, for example, in a range from 1 mm to 5 mm, and preferably in a range from 3 mm to 5 mm.

Bottom plate 130 has internal surface 130a (bottom surface) which faces first surface 201 of circuit board 200 disposed in a predetermined position inside of casing 100.

In bottom plate 130, first engagement hole 131 which first engagement claw 320 on first cover 300 engages and second engagement hole 132 which second engagement claw 420 on second cover 400 engages are formed. For example, first engagement hole 131 and second engagement hole 132 are through holes, and two first engagement holes 131 and two second engagement holes 132 are formed.

Top plate 140 has internal surface 140a which faces second surface 202 of circuit board 200. First top plate step portion 141 and second top plate step portion 142 are formed on internal surface 140a at an end portion of top plate 140 in the direction orthogonal to the sliding direction of circuit board 200. First top plate step portion 141 is formed on internal surface 140a along an edge portion of top plate 140, and second top plate step portion 142 is formed on internal surface 140a along another edge portion of top plate 140. A recess is formed in internal surface 140a (internal surface) of top plate 140 by forming first top plate step portion 141 and second top plate step portion 142.

Guide grooves 150 are formed on the external surfaces of first side wall 110 and second side wall 120. As will be later described, guide grooves 150 are used when power supply 1 is disposed in a housing of a lamp. In the present embodiment, guide grooves 150 are each configured by a pair of plate-shaped projections. This allows guide grooves 150 to also function as heat-dissipating fins. Note that guide grooves 150 are pairs of protruding ribs that stick out from the external surfaces of first side wall 110 and second side wall 120, yet the present disclosure is not limited thereto. Guide grooves 150 may be recessed grooves which are portions recessed in the external surfaces of first side wall 110 and second side wall 120.

Circuit board 200 disposed in casing 100 is a mounting substrate for mounting plural circuit components 210. Circuit board 200 includes first surface 201, and second surface 202 on an opposing side of first surface 201. Circuit components 210 are mounted on first surface 201. Specifically, first surface 201 is a mounting surface for mounting circuit components 210. Accordingly, on first surface 201, metal lines (not illustrated) for electrically connecting plural circuit components 210 are formed in a pattern having a predetermined shape. Note that the drawings do not illustrate all circuit components 210 mounted on circuit board 200 so that the drawings illustrate some of circuit components 210.

Metal lines are formed on second surface 202, as ground lines 220. Ground lines 220 are connected with, through, for instance, via holes formed in circuit board 200, metal lines having a ground potential in a power supply circuit which includes plural circuit components 210 mounted on first surface 201. Accordingly, ground lines 220 have the ground potential.

Ground lines 220 are formed on end portions of circuit board 200 in the direction orthogonal to the sliding direction of circuit board 200 (in other words, a width direction of circuit board 200). In the present embodiment, ground lines 220 extend in the sliding direction of circuit board 200, on widthwise end portions of circuit board 200. Specifically, ground lines 220 are formed along almost entire edge portions of the two long sides.

Ground lines 220 are in contact with top plate 140 of casing 100. Specifically, one of two ground lines 220 is in contact with the surface of first top plate step portion 141, and the other is in contact with the surface of second top plate step portion 142. This allows ground lines 220 to be grounded to metal casing 100.

Circuit board 200 having such a configuration is a printed-circuit board on which metal lines (such as copper foil) are formed. A resin substrate which is a resin-based substrate can be used as circuit board 200. As a resin substrate, for example, a glass epoxy board made of glass fibers and an epoxy resin (such as CEM-3 FR-4), or a substrate made of paper phenol or paper epoxy (such as FR-1) can be used.

In the present embodiment, a mounting substrate having first surface 201 and second surface 202 on both of which metal lines are formed is used as circuit board 200, yet circuit components 210 are mounted only on first surface 201. Note that circuit board 200 is a rigid substrate, but may be a flexible substrate.

The whole shape of circuit board 200 is substantially quadrilateral. Specifically, circuit board 200 is a printed-circuit board having a substantially rectangular shape in a plan view having a width of 66 mm to 75 mm, a length of 90 mm to 120 mm, and a thickness of about 1 mm.

Circuit board 200 is disposed in casing 100 in an orientation in which first surface 201 faces the internal surface of casing 100. Stated differently, first surface 201 on which circuit components 210 are mounted faces the internal surface of casing 100. In the present embodiment, first surface 201 faces internal surface 140a (top surface) of top plate 140. On the other hand, second surface 202 of circuit board 200 faces internal surface 130a of bottom plate 130.

As described above, circuit board 200 is glidingly inserted into casing 100. In casing 100, an end portion of circuit board 200 in the direction orthogonal to the sliding direction of circuit board 200 (that is, in the width direction of circuit board 200) is disposed between top plate 140 and first side wall step portion 111 formed on first side wall 110 of casing 100. Another end Portion of circuit board 200 in the direction orthogonal to the sliding direction of circuit board 200 is disposed between top plate 140 and second side wall step portion 121 formed on second side wall 120 of casing 100.

Circuit board 200 includes first notch 203 and second notch 204. First engagement portion 311 disposed on first protrusion 310 on first cover 300 engages first notch 203, and second engagement portion 411 disposed on second protrusion 410 on second cover 400 pages second notch 204.

In the present embodiment, first notches 203 are formed such that openings are provided in end portions of two long sides of circuit board 200 near first cover 300. Second notches 204 are formed such that openings are provided in end portions of two long sides of circuit board 200 near second cover 400. Specifically, four notches are formed in circuit board 200.

Plural circuit components 210 mounted on circuit board 200 are circuit elements included in the power supply circuit which generates power for causing the light sources of the lamp to emit light. In the present embodiment, plural circuit components 210 constitute a light circuit for turning on/off the LEDs.

For example, plural circuit components 210 are capacitive elements such as electrolytic capacitors or ceramic capacitors, coil elements (inductors) such as choke coils or choke transformers, transistor elements such as field-effect transistors, resistive elements such as resistors, or diodes, for instance. Note that plural circuit; components 210 are not limited thereto, and may include another circuit element such as a fuse or a noise filter.

Among circuit components 210, heat-generating components which generate heat by themselves include a coil element, a transistor element, a resistive element, and a diode, for instance.

Note that circuit components 210 may be circuit elements having leads or surface mount circuit elements.

Coupler 230 is disposed on circuit board 200. Coupler 230 is a surface mount connector component, and an input/output cable (not illustrated) is connected to coupler 230. Coupler 230 and the input/output cable are connected to each other electrically and mechanically.

Specifically, the input/output cable includes a power-input line, and power is input to coupler 230 through the input/output cable by inputting power from an external power supply such as a battery to circuit board 200 via the power-input line. The input/output cable also includes a power output line, and lighting power is output from coupler 230 through the input/output cable by outputting lighting power to the light sources (LEDs) of the lamp from circuit board 200 via the power output line. The input/output cable may further include a control signal line

The body of coupler 230 includes, for example, an insulating resin material such as a polyphenylene sulfide (PPS) resin or a polybutylene terephthalate (PBT) resin. Coupler 230 includes plural output connector terminals and plural input connector terminals for electrically connecting with the input/output cable.

Coupler 230 is mounted on first surface 201 of circuit board 200. In the present embodiment, coupler 230 is mounted on an end portion of circuit board 200 on the first cover 300 side. Note that coupler 230 is entirely housed in casing 100 in the present embodiment, but may slightly protrude from casing 100. Specifically, coupler 230 may stick out from opening 330 in first cover 300. Accordingly, coupler 230 and the input/output cable can be readily connected.

First cover 300 is a case cover attached to first opening 101 of casing 100. Specifically, first cover 300 is an end cap attached to casing 100 so as to cover first opening 101.

On the other hand, second cover 400 is a case cover attached to second opening 102 of casing 100. Specifically, second cover 400 is an end cap attached to casing 100 so as to cover second opening 102.

In the present embodiment, first cover 300 and second cover 400 are made of an insulating resin material such as a PBT resin, but the material is not limited thereto. First cover 300 and second cover 400 may be made of a metallic material.

First cover 300 includes a pair of first protrusions 310 protruding inwardly towards the interior of casing 100. The pair of first protrusions 310 are each formed into a structure having elastic force along a normal (the Z axis) to first surface 201 of circuit board 200. Specifically, first protrusions 310 have a folded structure which has a closed loop shape and elastically deforms along the Z axis. Accordingly, when first cover 300 is inserted into along the Y axis and attached to first opening 101, the pair of first protrusions 310 come into contact with first surface 201 of circuit board 200 and elastically deform so that pressing force which presses circuit board 200 towards top plate 140 is applied to circuit board 200.

Similarly, second cover 400 has a pair of second protrusions 410 protruding inwardly towards the interior of casing 100. The pair of second protrusions 410 are each formed into a structure having elastic force along a normal (the Z axis) to first surface 201 of circuit board 200. Specifically, similarly to first protrusions 310, second protrusions 410 have a folded structure which has a closed loop shape and elastically deforms along the Z axis. Accordingly, when second cover 400 is inserted into along the Y axis and attached to second opening 102, the pair of second protrusions 410 come into contact with first surface 201 of circuit board 200 and elastically deform so that pressing three which presses circuit board 200 towards top plate 140 is applied to circuit board 200.

Thus, first protrusions 310 and second protrusions 410 press circuit board 200 against the inner surface of casing 100. Specifically, circuit board 200 is pressed against inner surface 140a of top plate 140 of casing 100 by the elastic force exerted by first protrusions 310 and second protrusions 410. Specifically, circuit board 200 is held in a state of being elastically sandwiched between top plate 140 of casing 100 and first protrusions 310 and second protrusions 410. This maintains a state in which ground lines 220 on circuit board 200 are in contact with first top plate step portion 141 and second top plate step portion 142 on top plate 140.

First protrusions 310 on first cover 300 each have first engagement portion 311 that engages first notch 203 of circuit board 200. Similarly, second protrusions 410 on second cover 400 each have second engagement portion 411 that engages second notch 204 of circuit board 200. First engagement portions 311 and second engagement portions 411 are protrusions protruding from first protrusions 310 and second protrusions 410, respectively, for example.

First engagement portions 311 engage first notches 203 and second engagement portions 411 engage second notches 204, whereby first cover 300 and second cover 400 are attached to casing 100 in a state of being caught on the circuit board. Specifically, first notches 203 and second notches 204 function to prevent first cover 300 and second cover 400 from slipping off. In the present embodiment, first cover 300 and second cover 400 both pull the circuit board.

Furthermore, a pair of first engagement claws 320 are disposed on first cover 300. A pair of second engagement claws 420 are disposed on second cover 400. The pair of first engagement claws 320 engage the pair of first engagement holes 131 in bottom plate 130 of casing 100, and the pair of second engagement claws 420 engage the pair of second engagement hole 132 in bottom plate 130 of casing 100.

The outer edge portion of first cover 300 protrudes from the outer edge of first opening 101 of casing 100. In the present embodiment, the outer edge portion of first cover 300 extends beyond the outer edge of first opening 101 by at least 0.5 mm. Specifically, the amount of first cover 300 protruding from casing 100 is at least 0.5 mm.

Similarly, the outer edge portion of second cover 400 protrudes from the outer edge of second opening 102 of casing 100. In the present embodiment, the outer edge portion of second cover 400 extends beyond the outer edge of second opening 102 by at least 0.5 mm. Specifically, the amount of second cover 400 protruding from casing 100 is at least 0.5 mm.

Note that first cover 300 has opening 330 in a portion facing coupler 230. The shape and the size of opening 330 are almost the same as the shape and the size of the opening of coupler 230.

Heat-conducting members 500 are disposed between casing 100 and circuit board 200. Specifically, heat-conducting members 500 are disposed between top plate 140 of casing 100 and second surface 202 of circuit board 200.

Heat-conducting members 500 as described above are disposed, so that heat from circuit board 200 can be conducted efficiently to casing 100 since heat-conducting members 500 serve as heat transfer paths. Accordingly, heat-conducting members 500 may be disposed in regions of circuit board 200 where the temperature goes higher. Specifically, the temperature rises in portions of circuit board 200 where circuit components 210 that are heat-generating components are mounted, and thus heat-conducting members 500 may be formed to overlap circuit; components 210 that are heat-generating components, in a plan view of circuit board 200.

Heat-conducting members 500 are made of an insulating resin material, for example. For example, heat-conducting members 500 have a configuration in which inorganic filler having high heat conductivity is dispersed in an insulating adhesive made of a silicone resin, for example.

Heat-conducting members 500 may be made of a hardening adhesive resin. For example, heat-conducting members 500 are insulating adhesive made of a thermosetting resin or an ultraviolet curing resin.

### Manufacturing Method

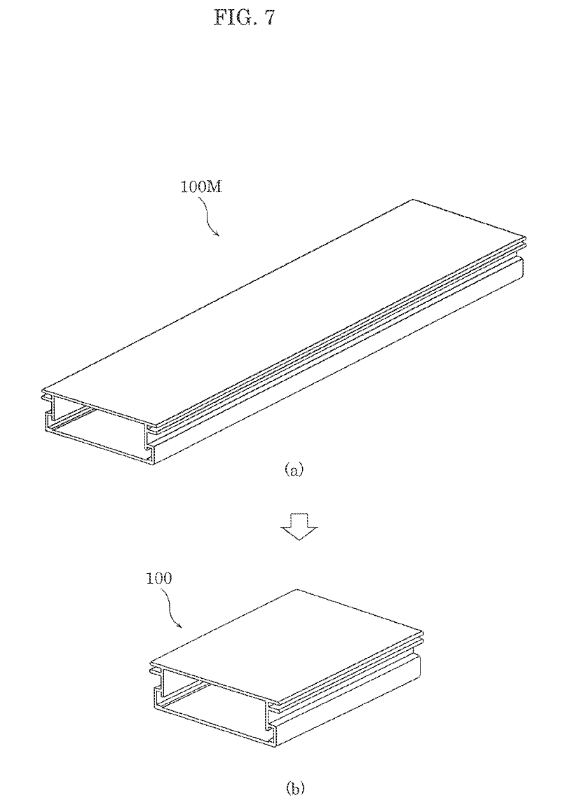

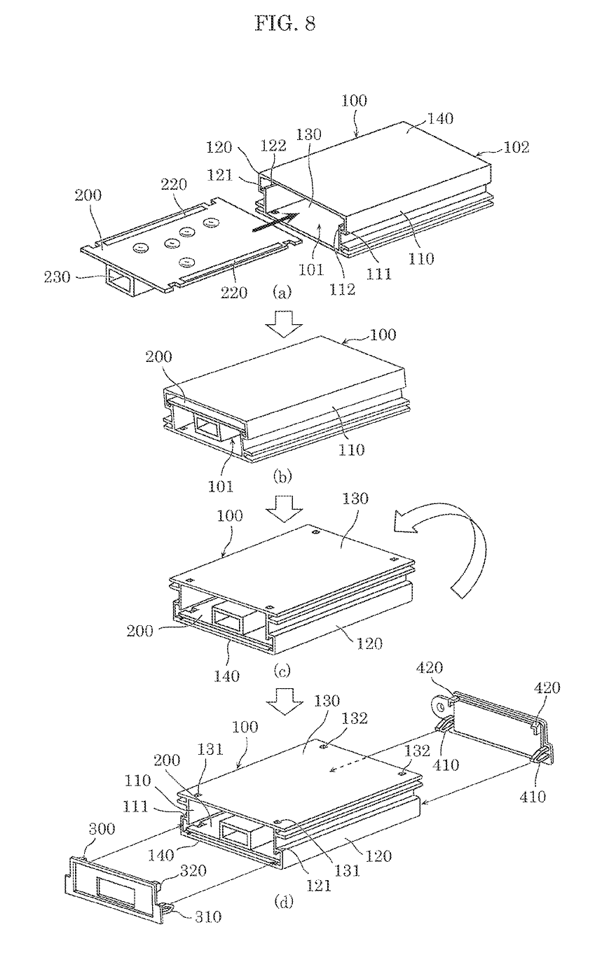

The following describes a method for manufacturing power supply 1 according to the present embodiment, with reference to FIGS. 7 and 8. FIG. 7 is a diagram for describing examples of steps of producing casing 100 in power supply 1 according to Embodiment 1. FIG. 8 is a diagram for describing a method for manufacturing power supply 1 according to Embodiment 1.

When power supply 1 is to be manufactured, firstly, a metallic material is extruded to produce in advance substantially tubular casing 100. In this case, as illustrated in (a) in FIG. 7, an elongated metallic material such as an aluminum material is extruded to produce mother component 100M which is an elongated extruded component. As illustrated in (b) in FIG. 7, casing 100 having a desired length can be produced by cutting mother component 100M at a desired length.

Note that casing 100 having the length illustrated in (b) in FIG. 7 may be produced without cutting mother component 100M, yet casings 100 having little individual variation in length and good length precision can be readily produced by cutting out casings 100 from mother component 100M. If the method of cutting out casings 100 from mother component 100M is employed, even when circuit board 200 is to have a longer or shorter length due to specification change, casings 100 having a desired length can be readily produced in a short time period without incurring additional cost.

After producing casing 100, as illustrated in (a) in FIG. 8, circuit board 200 on which circuit components 210 are mounted is inserted from one of first opening 101 and second opening 102 of casing 100, and is disposed in casing 100. In the present embodiment, circuit board 200 is inserted from first opening 101.

In this process, as illustrated in (a) in FIG. 8, casing 100 is disposed such that top plate 140 is located on the upper side, and circuit board 200 is slidingly inserted into casing 100 with first surface 201 on which circuit components 210 are mounted facing downward.

Specifically, circuit board 200 having second surface 202 to which heat ducting members 500 are applied in predetermined positions is slidingly inserted into casing 100 with second surface 202 facing upward, and circuit board 200 is housed in casing 100 as illustrated in (b) in FIG. 8.

At this time, as illustrated in FIG. 9, circuit board 200 is slid to the inside of casing 100 in a state in which first surface 201 of circuit board 200 is in contact with first rib 112 and second rib 122 so that circuit board 200 is supported by first rib 112 and second rib 122.

In this manner, not only circuit board 200 can be slidingly inserted stably so as not to change the vertical position of circuit board 200, but also heat-conducting members 500 can be prevented from unexpectedly adhering to the inner surface of casing 100 even if heat-conducting members 500 applied to circuit board 200 supported by first rib 112 and second rib 122 have not yet cured. Furthermore, ground lines 220 formed on second surface 202 of circuit board 200 do not come into contact with the inner surface of casing 100, and thus can be prevented from being scraped or coming off by being rubbed against the inner surface of casing 100 when circuit board 200 is slid.

Next, after disposing circuit board 200 in casing 100, as illustrated in (c) in FIG. 8, casing 100 is rotated 180 degrees so as to be turned upside down. Specifically, the vertical orientation of casing 100 is changed so that bottom plate 130 is located on the upper side.

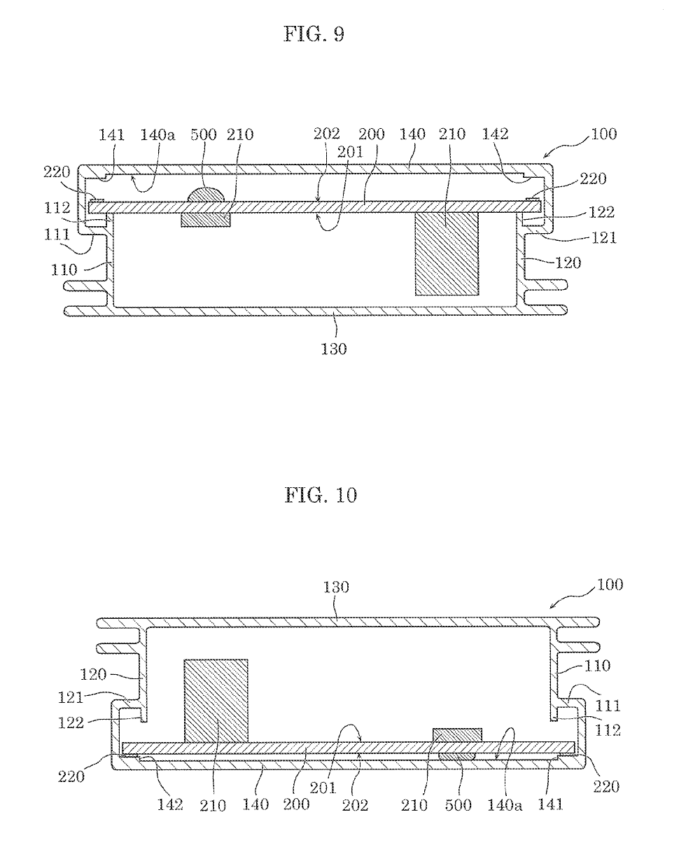

Accordingly, circuit board 200 moves apart from first rib 112 and second rib 122 and falls on the top plate 140 side in a lower position, as illustrated in FIG. 10. As a result, heat-conducting members 500 applied to circuit board 200 come into contact with inner surface 140a of top plate 140, and are spread due to the self-weight of circuit board 200. At the same time, two ground lines 220 formed on second surface 202 of circuit board 200 come into contact with first top plate step portion 141 and second top plate step portion 142 on top plate 140.

Next, first cover 300 and second cover 400 are attached to casing 100 as illustrated in (d) in FIG. 8. At this time, first cover 300 is attached to casing 100 so that first opening 101 of casing 100 is covered by first cover 300. Furthermore, second cover 400 is attached to casing 100 so that second opening 102 of casing 100 is covered by second cover 400.

Specifically, one of the pair of first protrusions 310 on first cover 300 is pushed in between circuit board 200 and first side wall step portion 111 on first side wall 110, and also the other of the pair of first protrusions 310 on first cover 300 is pushed in between circuit board 200 and second side wall step portion 121 on second side wall 120, in order that first cover 300 covers first opening 101.

Accordingly, the pair of first protrusions 310 elastically deform, and the elastic force exerted by first protrusions 310 applies pressing force to an end portion of circuit board 200 on the first cover 300 side, whereby circuit board 200 is pressed towards top plate 140.

Similarly, one of the pair of second protrusions 410 on second cover 400 is pushed in between circuit board 200 and first side wall step portion 111 on first side wall 110, and also the other of the pair of second protrusions 410 on second cover 400 is pushed in between circuit board 200 and second side wall step portion 121 on second side wall 120, in order that second cover 400 covers second opening 102.

Accordingly, the pair of second protrusions 410 elastically deform, and the elastic force exerted by second protrusions 410 applies pressing force to an end portion of circuit board 200 on the second cover 400 side, whereby circuit board 200 is pressed towards top plate 140.

As described above, both end portions of circuit board 200 in the sliding direction are pressed towards top plate 140 by elastic force exerted by first protrusions 310 on first cover 300 and second protrusions 410 on second cover 400. Thus, ground lines 220 on circuit board 200 reliably come into contact with first top plate step portion 141 and second top plate step portion 142 on top plate 140 and furthermore, this contact state is maintained.

As illustrated in FIG. 5, when first cover 300 and second cover 400 are attached to casing 100, first engagement portions 311 of first: protrusions 310 on first cover 300 engage first notches 203 in circuit board 200, and second engagement portions 411 of second protrusions 410 on second cover 400 engage second notches 204 in circuit board 200. Accordingly, first cover 300 and second cover 400 are fixed to circuit board 200.

As illustrated in FIG. 6, when first cover 300 and second cover 400 are attached to casing 100, first engagement claws 320 on first cover 300 engage first engagement holes 131 in bottom plate 130 of casing 100, and second engagement claws 420 on second cover 400 engage second engagement holes 132 in bottom plate 130 of casing 100. Accordingly, first cover 300 and second cover 400 are fixed to casing 100.

Power supply 1 illustrated in FIGS. 1 and 2 can be produced as described above.

Note that after turning casing 100 upside down, curing treatment for heat-conducting members 500 may be separately performed at arbitrary timing, or heat-conducting members 500 may be cured by air drying, without separately performing curing treatment for heat-conducting members 500.

In addition, the order in which first cover 300 and second cover 400 are attached may be an order in which first cover 300 is attached and then second cover 400 is attached, and vice versa.

### Advantageous Effects and Others

As stated above, power supply 1 according to the present embodiment includes: casing 100 including a heat-conducting material and having an inner surface and an outer surface, casing 100 being a one-piece component having a substantially tubular shape; circuit board 200 disposed in casing 100, circuit board 200 having first surface 201 on which one or more circuit components 210 are mounted and second surface 202 on an opposing side of first surface 201; first cover 300 disposed over first opening 101 of casing 100; and second cover 400 disposed over second opening 102 of casing 100. Further, first surface 201 of circuit board 200 faces the inner surface of casing 100.

This configuration allows heat generated by circuit components 210 to be dissipated by efficiently conducting the heat to casing 100. In particular, since casing 100 is formed into a one-piece component having a substantially tubular shape, the entirety of casing 100 is completely connected without breaks. Thus, compared with a conventional case where a casing includes a plurality of parts, thermal conductivity of the entirety of casing 100 can be improved. Specifically, if the casing includes a plurality of parts, a thin air layer is present at portions where the plurality of parts are connected, so that thermal resistance occurs. Nevertheless, such thermal resistance is prevented from occurring by forming casing 100 into a one-piece component having a substantially tubular shape as in the present embodiment. Moreover, first surface 201 of circuit board 200 on which circuit components 210 are mounted faces the inner surface of casing 100, and thus heat generated by circuit components 210 can be efficiently conducted to casing 100.

This eliminates need to add a control circuit which reduces the light output of a light source according to a rise in the temperature, add an electrically driven fan, and employ a large casing, as measures for dissipating heat. Thus, an increase in the size (volume) of casing 100 is inhibited so that the size of power supply 1 can be readily reduced.

Moreover, circuit board 200 is disposed inside of casing 100 formed into a one-piece component having an approximately tubular shape, whereby water resistance can be improved. Specifically, if the casing includes a plurality of parts, water may ingress to the inside even from narrow gaps present at portions where the plurality of parts are connected, yet such ingress of water to the inside can be prevented by forming casing 100 into a one-piece component having a substantially tubular shape as in the present embodiment

Thus, the structure of power supply 1 according to the present embodiment achieves a power supply having excellent heat dissipating capability and water resistance, without increasing the size of the power supply.

In power supply 1 according to the present embodiment, the outer surface of casing 100 may account for at least 80% of a total outer surface area of power supply 1.

This configuration achieves a power supply having still higher heat dissipating capability. Moreover, the surface areas of first opening 101 and second opening 102 of casing 100 can be decreased, and thus electromagnetic compatibility (EMC) can be improved.

In power supply 1 according to the present embodiment, first cover 300 includes first protrusion 310 protruding inwardly towards interior of casing 100, second cover 400 includes second protrusion 410 protruding inwardly towards the interior of casing 100, and first protrusion 310 and second protrusion 410 press circuit board 200 against the inner surface of casing 100.

This configuration allows circuit board 200 to be stably held in casing 100.

In this case, in power supply 1 according to the present embodiment, first engagement portion 311 of first protrusion 310 on first cover 300 engages first notch 203 in circuit board 200, and second engagement portion 411 of second protrusion 410 on second cover 400 engages second notch 204 in circuit board 200.

This configuration can readily fix casing 100, circuit board 200, first cover 300, and second cover 400 to one another at low cost, and furthermore achieves a highly reliable power supply. The following describes this point.

It is conceivable to use a fastening component such as a screw or a rivet when circuit board 200 and casing 100 are to be fixed. However, when a fastening component such as a screw is separately used as mentioned above, an increase in the number of components results in an increase in component cost and assembly cost.

When first cover 300 and second cover 400 are fixed to casing 100, it is conceivable to form in casing 100 circular holes or tap holes which extend along the tubular axis of casing 100, and fasten first cover 300 and second cover 400 to casing 100 using tapping screws, for instance. However, in this manner, not only component cost and assembly cost increase due to the increase in the number of components, but also foreign metal is generated by screwing the tapping screws and left on circuit board 200, which causes failure and decreases reliability.

In view of this, according to the structure of power supply 1 according to the present embodiment, first cover 300 and second cover 400 are locked with respect to circuit board 200 by disposing first cover 300 over first opening 101 of casing 100 in which circuit board 200 is inserted and also disposing second cover 400 over second opening 102 of casing 100 in which circuit board 200 is inserted. Specifically, casing 100, circuit board 200, first cover 300, and second cover 400 can be fixed to one another without separately using, for instance, a screw, by disposing first cover 300 over first opening 101 and also disposing second cover 400 over second opening 102. Moreover, there is no need to use a tapping screw, and thus no foreign metal is generated, so that excellent reliability can be achieved.

In power supply 1 according to the present embodiment, the outer edge portions of first cover 300 and second cover 400 protrude from first opening 101 and second opening 102. Specifically, an outer edge portion of first cover 300 extends beyond an outer edge of first opening 101 by at least 0.5 mm, and an outer edge portion of second cover 400 extends beyond an outer edge of second opening 102 by at least 0.5 mm.

This configuration allows the edges of the end surfaces (such as cut surfaces) of first opening 101 and second opening 102 of casing 100 to be covered. This prevents a user from getting injured by sharp edges of the end surfaces of first opening 101 and second opening 102. In addition, even if the end surfaces of first opening 101 and second opening 102 include, for instance, burrs, a user can be prevented from getting injured by the burrs. Accordingly, highly safe power supply 1 that can be readily handled can be achieved by adopting a structure in which the outer edge portions of first cover 300 and second cover 400 protrude from first opening 101 and second opening 102.

In power supply 1 according to the present embodiment, casing 100 includes: first side wall 110; second side wall 120; bottom plate 130; and top plate 140, a first end portion of circuit board 200 in the width direction is disposed between top plate 140 and first side wall step portion 111 formed on first side wall 110, and a second end portion of circuit board 200 in the width direction is disposed between top plate 140 and second side wall step portion 121 provided on second side wall 120.

According to this configuration, circuit board 200 can be readily housed in casing 100 by slidingly inserting circuit board 200 into casing 100.

In power supply 1 according to the present embodiment, first side wall 110 includes first rib 112 protruding, from first side wall step portion 111, towards first surface 201 of circuit board 200, and second side wall 120 includes second rib 122 protruding, from second side wall step portion 121, towards first surface 201 of circuit board 200.

According to this configuration, circuit board 200 can be supported by first rib 112 and second rib 122 when circuit board 200 is slidingly inserted into casing 100, and thus readily disposed in a predetermined position inside of casing 100.

In power supply 1 according to the present embodiment, a spacing between first rib 112 and first surface 201 of circuit board 200 is in a range from 1 mm to 5 mm, and a spacing between second rib 122 and first surface 201 of circuit board 200 is in a range from 1 mm to 5 mm.

According to this configuration, even if first opening 101 and second opening 102 are narrow, circuit board 200 can be inserted into casing 100, and power supply 1 can be assembled. Accordingly, an extra space is not included in casing 100, and thus the size of casing 100 is prevented from being unnecessarily increased. Further, clearance in a range from 1 mm to 5 mm is provided between first surface 201 of circuit board 200 and each of first rib 112 and second rib 122, so that the clearance can be used as a space when an explosion proof valve of an electrolytic capacitor is opened, and at the same time, a short circuit due to dew condensation can be prevented.

In power supply 1 according to the present embodiment, circuit board 200 includes ground line 220 disposed on second surface 202 of circuit board 200, ground line 220 being disposed in an end portion of circuit board 200 in the width direction, and ground line 220 being in contact with top plate 140.

In this manner, ground line 220 is formed on second surface 202 (on an opposing side of the component side) of circuit board 200 so that the surface area for ground line 220 can be increased. Then, comparatively large ground line 220 is in contact with top plate 140 of casing 100, whereby ground line 220 and casing 100 are placed in an electrically conductive state. Accordingly, improvement in EMC and stable operation of power supply 1 can be achieved.

Moreover, in the present embodiment, first protrusion 310 on first cover 300 and second protrusion 410 on second cover 400 press circuit board 200 towards top plate 140, and thus without circuit board 200 being inclined, ground line 220 and top plate 140 can be reliably maintained in contact in a large area. Accordingly, EMC can be further improved, and furthermore, power supply 1 can be stably operated.

In power supply 1 according to the present embodiment, first top plate step portion 141 and second top plate step portion 142 are formed on inner surface 140a of top plate 140. One of a pair of ground lines 220 is in contact with first top plate step portion 141, and the other of the pair of ground lines 220 is in contact with second top plate step portion 142.

This configuration allows a recess to be formed by depressing inner surface 140a of top plate 140 while maintaining top plate 140 and ground line 220 in contact with each other. Accordingly, for example, the tips of leads of circuit components 210 mounted on first surface 201 can be housed in the recess.

Power supply 1 according to the present embodiment further includes: heat-conducting member 500 disposed between top plate 140 and second surface 202 of circuit board 200.

This configuration allows heat from circuit board 200 to be efficiently conducted to top plate 140 via heat conductive member 500, and thus can achieve power supply 1 having still higher heat dissipating capability.

In this case, when power supply 1 is disposed, top plate 140 may be located vertically above bottom plate 130. Accordingly, heat from circuit board 200 can be conducted in the directions of heat flow and air convection (that is, with low heat resistance). Specifically, heat from circuit board 200 is conducted to top plate 140 via heat conductive member 500 present on the upper side of circuit board 200, and then is conducted to an air layer above top plate 140. Stated differently, heat from circuit board 200 is always conducted upward and still upward, rather than being conducted downward. Accordingly, heat from circuit board 200 can be smoothly dissipated. As a result, the size of casing 100 can be reduced.

In power supply 1 according to the present embodiment, heat-conducting member 500 is disposed to overlap circuit component 210 which is a heat-generating component in a plan view of circuit board 200.

In circuit board 200, a temperature around the heat-generating component which is a source of heat production is increased, and thus, this configuration allows heat from circuit board 200 to be efficiently dissipated via heat conductive member 500.

In power supply 1 according to the present embodiment, heat-conducting member 500 includes a hardening adhesive resin.

According to this configuration, even if power supply 1 is disposed in a vibrating environment (such as in a vehicle), heat conductive member 500 can maintain thermal connection between circuit board 200 and casing 100 and furthermore, cracks in the solder, for instance, can be inhibited from appearing due to mechanical stress applied to circuit component 210. Furthermore, insulation (positional relationship) between circuit board 200 and casing 100 can also be maintained.

In power supply 1 according to the present embodiment the heat-conducting material included in casing 100 is a metallic material.

This configuration allows heat from circuit board 200 to be efficiently conducted to casing 100, and thus achieves power supply 1 having still enhanced heat dissipating capability. Furthermore, EMC can be improved.

In power supply 1 according to the present embodiment, casing 100 is an extruded aluminum casing.

This configuration allows the inner surface of casing 100 to be a smooth surface without fine unevenness, and eliminates the need of machining (such as cutting or tapping) the inside of casing 100 so that foreign metal is not generated. Accordingly, the short circuit failure does not occur in circuit board 200, and thus power supply 1 having high reliability can be achieved.

A method for manufacturing power supply 1 according to the present embodiment includes: forming casing 100 having a substantially tubular shape by extruding a metallic material, casing 100 being formed to have first opening 101 and second opening 102; inserting, in a sliding manner, circuit board 200 into casing 100 via one of first opening 101 and second opening 102 of casing 100, circuit board 200 having first surface 201 on which one or more circuit components 210 are mounted and second surface 202 on an opposing side of first surface 201; attaching first cover 300 over first opening 101; and attaching second cover 400 over second opening 102. When circuit board 200 is inserted into casing 100, circuit board 200 is inserted with first surface 201 facing downward.

In this manner, in the present embodiment, casing 100, circuit board 200, first cover 300, and second cover 400 can be entirely assembled only in one direction along the tubular axis of casing 100, using first opening 101 or second opening 102. Accordingly, since special operations are not required, defects resulting from assembly operation can be reduced. Furthermore, assembly operation can be conducted with ease, and thus even if work quality deteriorates depending on an operation area such as a country or capability of a worker, deterioration of product quality can be inhibited. Besides, not many components are used, and thus the product can be readily disassembled after use so that energy saving is achieved.

### Embodiment 2

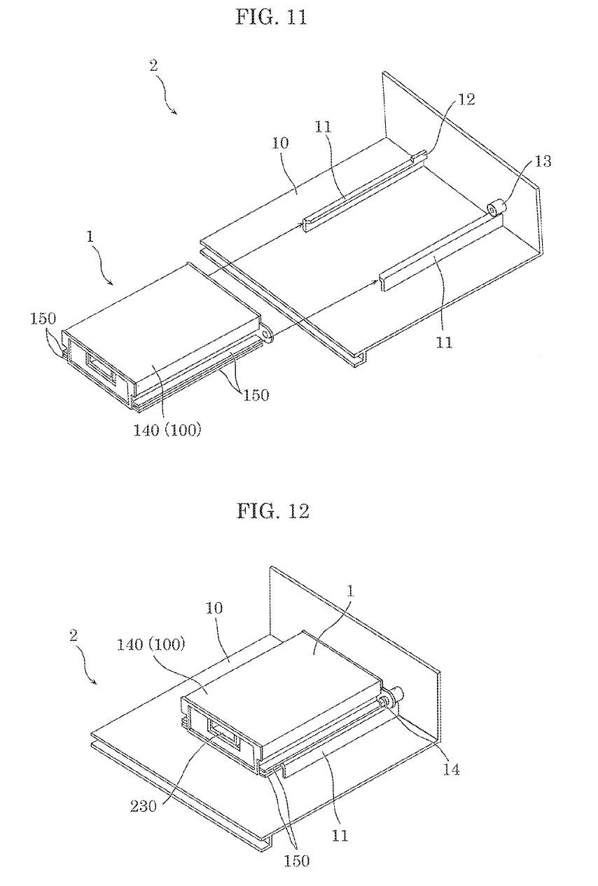

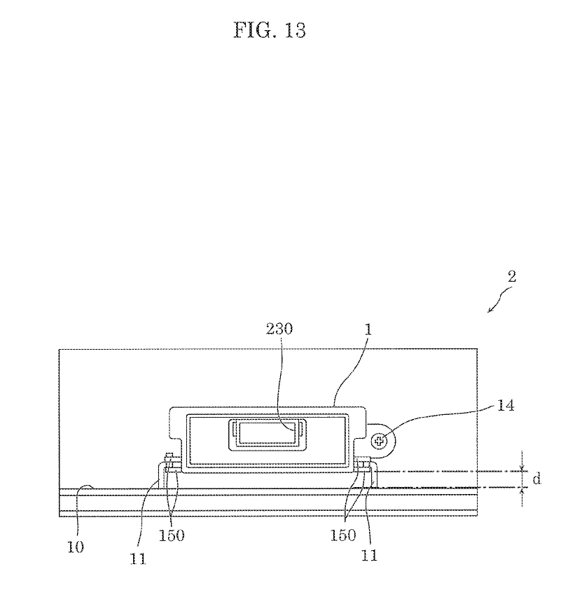

The following describes lamp 2 according to Embodiment 2 with reference to FIGS. 11 to 13. FIG. 11 illustrates a state when power supply 1 is attached to housing 10 of lamp 2 according to Embodiment 2. FIG. 12 is a perspective view illustrating a state when power supply 1 is disposed in housing 10 of lamp 2 illustrated in FIG. 11. FIG. 13 is a front view illustrating a state when power supply 1 is disposed in housing 10 of lamp 2 illustrated in FIG. 11. Note that FIGS. 11 to 13 illustrate part of a configuration of housing 10.

As illustrated in FIG. 11, slide rails 11 are disposed on housing 10 of lamp 2. Slide rails 11 are guide rails serving as guides when power supply 1 is slid on and disposed in housing 10.

Specifically, when power supply 1 is disposed in housing 10, guiding grooves 150 disposed on casing 100 of power supply 1 receive slide rails 11, and power supply 1 is slid along slide rails 11 and pushed into the back. At this time, stopper 12 is disposed on housing 10, and thus power supply 1 conies into contact with stopper 12 and stops. Accordingly, power supply 1 can be disposed in a predetermined position in housing 10, as illustrated in FIG. 12.

Power supply 1 and housing 10 are fixed using screw 14. Specifically, screw 14 is put in a through hole provided in second cover 400 of power supply 1, and is screwed into threaded hole 13 of housing 10, whereby power supply 1 can be fixed to housing 10.

Accordingly, guiding grooves 150 of casing 100 receive slide rails 11 on housing 10, and power supply 1 is slid along slide rails 11, whereby power supply 1 can be readily attached to housing 10.

In the present embodiment, power supply 1 is disposed such that first surface 201 of circuit board 200 faces vertically downward towards bottom plate 130. Specifically, circuit components 210 mounted on circuit board 200 face towards the ground.

Even if dew condensation occurs or water ingresses into lamp (housing 10), this configuration inhibits water from collecting on first surface 201 of circuit board 200. This inhibits circuit components 210 mounted on first surface 201 and/or metal lines formed on first surface 201 from deteriorating or getting damaged due to water. Even in the case where foreign metal (such as metal powder, machining dust, or a solder ball) is present in power supply 1, such foreign metal falls below circuit board 200, and thus foreign metal is inhibited from accumulating on first surface 201 of circuit board 200 which is the lower surface. Accordingly, circuit components 210 mounted on first surface 201 and metal lines formed on first surface 201 can be inhibited from short-circuiting with such foreign metal. As described above, power supply 1 is disposed such that first surface 201 of circuit board 200 faces vertically downward towards bottom plate 130, whereby highly reliable lamp 2 can be achieved.

As illustrated in FIG. 13, in the present embodiment, a space is present between the surface of housing 10 on which slide rails 11 are disposed and casing 100 of power supply 1. Stated differently, a space is formed under power supply 1.

This configuration secures heat-dissipating planes not only above and on the side of power supply 1, but also under power supply 1, and thus achieves an increase in heat dissipation. This achieves reduction in the size of and stable operation of power supply 1. Moreover, a state where power supply 1 is separated from housing 10 is achieved by forming a space under power supply 1, and thus even if dew condensation occurs in or water ingresses to the inside of lamp 2, ingress of water to the inside of power supply 1 can be inhibited.

Note that spacing d of a gap between the surface of housing 10 on which slide rails 11 are disposed and casing 100 of power supply 1 may be at least 8 mm, in terms of heat dissipation. Furthermore, at least 8 mm space from power supply 1 may be secured not only under power supply 1, but also above and on both lateral sides of power supply 1.

### Embodiment 3

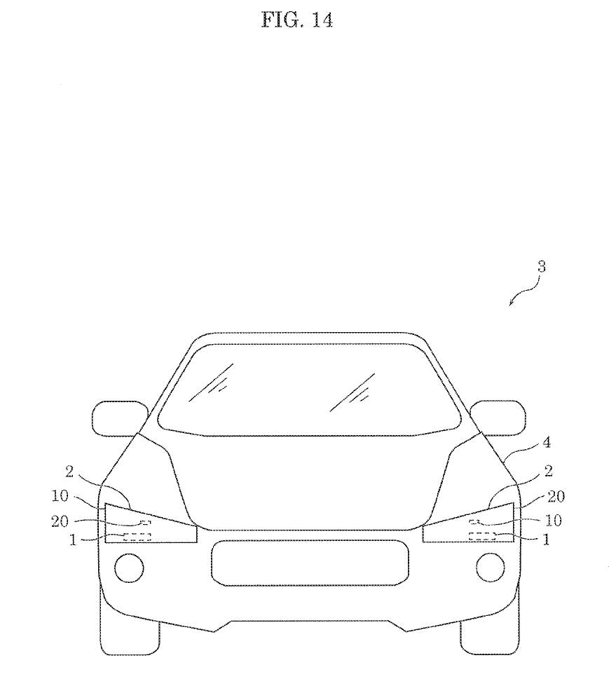

The following describes vehicle 3 according to Embodiment 3 with reference to FIG. 14. FIG. 14 is a front view of vehicle 3 according to Embodiment 3.

Vehicle 3 is an example of a movable device. In the present embodiment, vehicle 3 is a four-wheel car, and examples thereof include a gasoline car, an electric car, a hybrid car, and so on.

As illustrated in FIG. 14, vehicle 3 includes lamps 2 (lights), and body 4 which includes lamp 2. In the present embodiment, lamps 2 are headlights (headlamps), and disposed in right and left front portions of body 4.

Body 4 includes housings 10 for housing lamps 2, light sources 20 disposed inside of housings 10, and power supplies 1 disposed inside of housings 10. Power supply 1 generates power for causing light source 20 to emit light, and supplies the power to light source 20.

Housing 10 is a metal or resin casing, for example, and has an opening through which light from lamp 2 is emitted. A light-transmitting front cover (headlight cover) is disposed over the opening. Light source 20 is an LED module which includes one or more LEDs, for example, and emits white light ahead of vehicle 3 as illumination light.

Thus, power supply 1 in the present embodiment can be used for a headlight of vehicle 3, for instance.

### Variation

The above has described the power supply, the lamp, and the vehicle according to the present disclosure, based on Embodiments 1 to 3, yet the present disclosure is not limited to Embodiments 1 to 3 above.

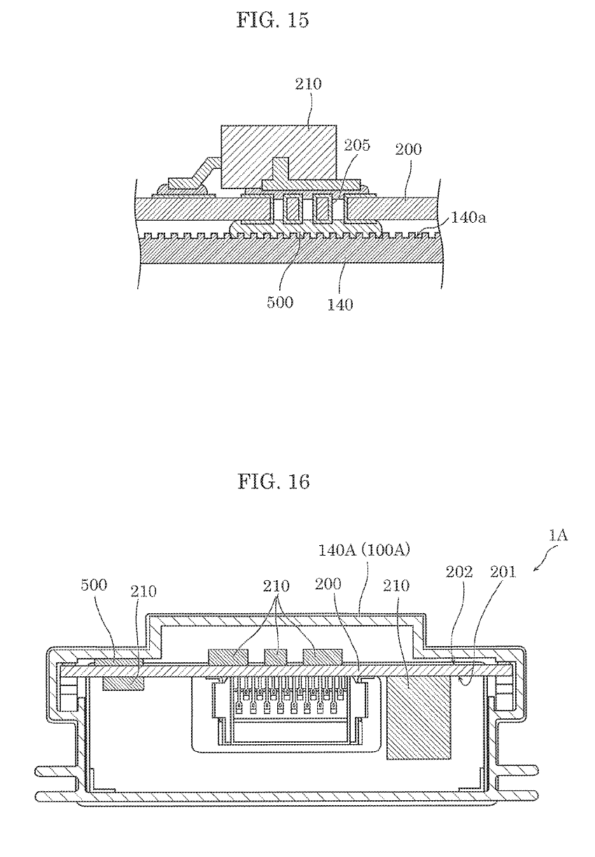

For example, in Embodiments 1 to 3 above, inner surface 140a of top plate 140 is a flat surface, yet inner surface 140a of top plate 140 may be an uneven surface where recesses and protrusions are formed, as illustrated in FIG. 15. The recesses and protrusions of the uneven surface are minute splines, for example. Heat-conducting member 500 is formed on the uneven surface, so that the bonding strength between circuit board 200 and top plate 140 improves according to an anchor effect. Accordingly, heat-conducting member 500 can be inhibited from coming off, and thus heat conduction effects produced by heat-conducting member 500 can be maintained. Note that as illustrated in FIG. 15, heat dissipating vias 205 are disposed on circuit board 200 and in contact with heat-conducting member 500, so that heat generated by circuit component 210 that is a heat-generating component can be dissipated more efficiently.

In Embodiments 1 to 3 above, circuit components 210 are mounted only on first surface 201 among first surface 201 and second surface 202 of circuit board 200, yet the present disclosure is not limited thereto. For example, as power supply 1A illustrated in FIG. 16, circuit components 210 may be mounted on both first surface 201 and second surface 202 of circuit board 200. In this case, a recess may be formed in top plate 140A so as to create a 1 mm to 10 mm cavity between circuit board 200 and top plate 140A. An about 0 mm to 1 mm cavity narrower than the cavity created by the above recess may be provided between circuit board 200 and top plate 140A. Circuit component 210 that is a heat-generating component and mounted on first surface 201 of circuit board 200 may be mounted in a position corresponding to the narrow cavity. Accordingly, heat generated by the heat-generating component can be efficiently conducted to top plate 140A. Note that heat-conducting member 500 may be further provided in the narrow cavity. Thus, the size of circuit board 200 can be reduced by mounting circuit components 210 on both surfaces of circuit board 200. As a result, the size of power supply 1 can be reduced, and also high functionality can be given to power supply 1.

As power supply 1B illustrated in FIG. 17, casing 100B which includes plural heat-dissipating fins 160 may be used. In this case, plural heat-dissipating fins 160 may be integrally formed with casing 100B. Specifically, casing 100B which includes heat-dissipating fins 160 can be produced by extruding an aluminum material. Accordingly, plural heat-dissipating fins 160 extend along the tubular axis of casing 100B, and are aligned in a direction crossing the tubular axis of casing 100B. Thus, since casing 100E includes plural heat-dissipating fins 160, the overall length of power supply 1B (casing 100B) is inhibited from changing (in the amount of extension), and also casing 100E can be readily applied for a power supply which generates a greater amount of heat as a whole. Furthermore, casing 100B can withstand use at a still higher temperature. Time periods for development and commercialization can also be shortened. In addition, single assembly operation also achieves improvement in reliability.

Guiding grooves 150 are provided on the bottom plate 130 side in Embodiments 1 to 3 above, yet the present disclosure is not limited thereto. For example, guiding grooves 150 may be disposed on the top plate 140 side (circuit board 200 side). This allows a power supply to be disposed in the upper portion of the housing in the lamp, without deteriorating heat dissipating capability and water resistance of the power supply and further without changing the assembly structure of the power supply. Accordingly, flexibility of the design and reliability of the lamp can be improved.

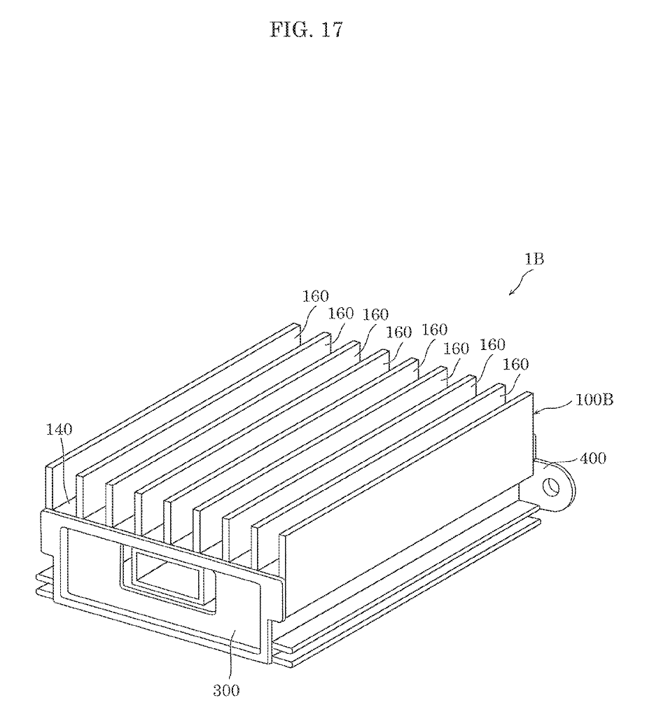

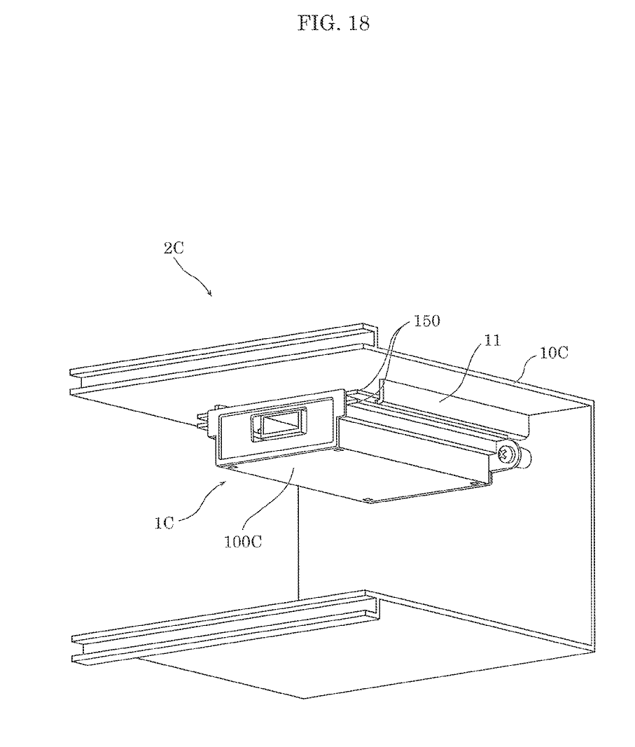

In Embodiment 2 above, power supply 1 is disposed on a lower component of housing 10, yet the present disclosure is not limited thereto. For example, as lamp 2C illustrated in FIG. 18, power supply 1C may be disposed on an upper component of housing 10C, in this case, slide rails 11 are disposed on the upper component of housing 10C. Guiding grooves 150 of power supply 1 are disposed on an upper portion of casing 1000. In this manner, by disposing power supply 1C near the upper surface of housing 10C, power supply 1C can be disposed in the upper portion in lamp 2C without deteriorating heat dissipating capability and water resistance of power supply 1C and further without changing the assembly structure of power supply 1C. Accordingly, flexibility of the design and reliability of lamp 2C can be improved.

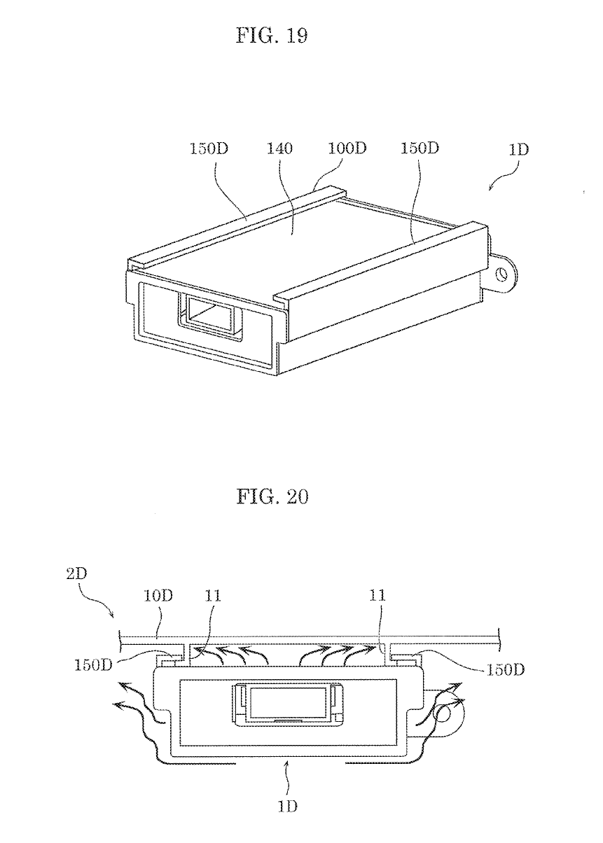

In Embodiments 1 to 3 above, guiding grooves 150 are disposed on first side wall 110 and second side wall 120, yet the present disclosure is not limited thereto. For example, as power supply 1D illustrated in FIG. 19, a pair of inwardly bent guiding grooves 150D each having an L-shaped cross section may be disposed on both edge portions of top plate 140 of casing 100D. In this case, as illustrated in FIG. 20, power supply 1D is attached such that power supply 1D is suspended from slide rails 11 on housing 10D of lamp 2D. Note that the arrows illustrated in FIG. 20 schematically illustrate flows of heat dissipated from power supply 1D. According to power supply 1D in this variation, the area occupied by power supply 1D in lamp 2D can be decreased.

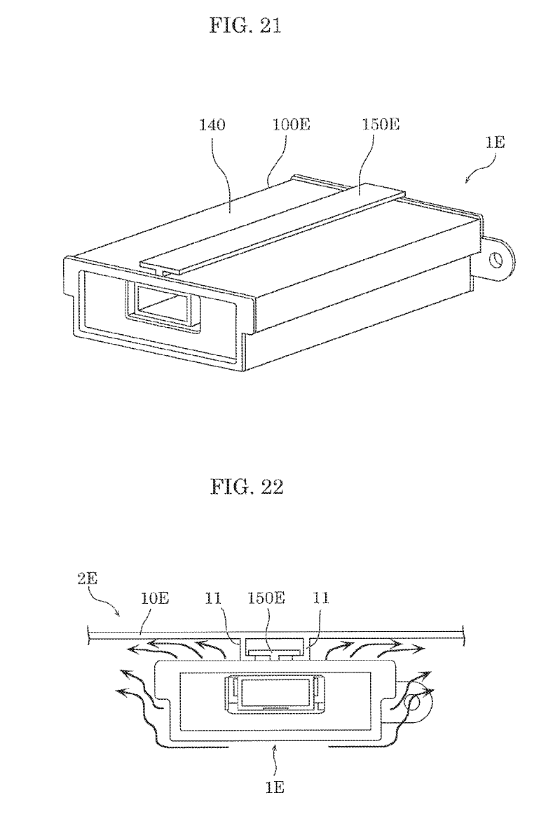

As power supply illustrated in FIG. 21, guiding grooves 150E having a T-shaped cross section may be disposed on the center portion of top plate 140 of casing 100E. In this case, as illustrated in FIG. 22, power supply 1E is attached such that power supply 1E is suspended from a pair of slide rails 11 disposed on the upper component of housing 10E of lamp 2E. According to power supply 1E in this variation, the area occupied by power supply 1E in lamp 2E can be decreased, similarly to power supply 1D illustrated in FIG. 20. Furthermore, according to power supply 1E in this variation, as illustrated by the arrows in FIG. 22, a flow of open air (heat flow) heated by heat dissipated from power supply 1E 9 is smoothly caused, and thus heat dissipating capability improves compared with the case of power supply 1D described above. This readily achieves small lamp 2E.

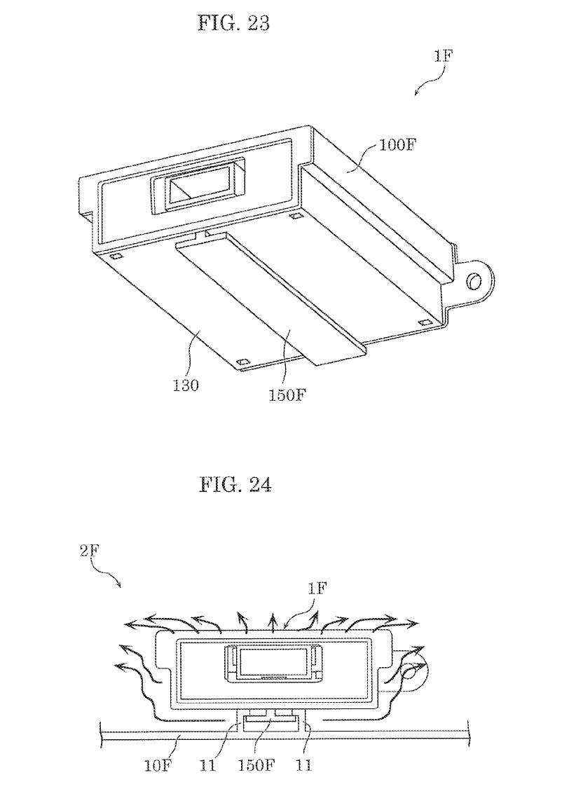

As power supply 1F illustrated in FIG. 23, guiding grooves 150F having a T-shaped cross-section may be provided on the center portion of bottom plate 130 of casing 100F. In this case, as illustrated in FIG. 24, power supply 1F can be attached to a pair of slide rails 11 disposed on a lower component of housing 10F of lamp 2F. According to power supply 1F in this variation, the area occupied by power supply 1F in lamp 2F can be decreased, similarly to power supply 1E illustrated in FIG. 22. Furthermore, according to power supply 1F in this variation, as illustrated by the arrows in FIG. 24, a flow of open air (heat flow) heated by heat dissipated from power supply 1F is smoothly caused, and thus heat dissipating capability improves similarly to the case of power supply 1E described above. This readily achieves small lamp 2F,

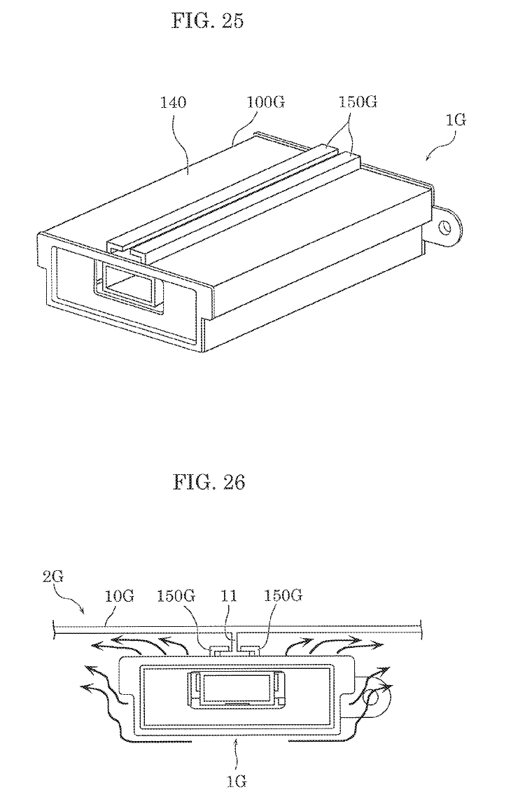

As power supply 1G illustrated in FIG. 25, a pair of inwardly bent guiding grooves 150G each having an L-shaped cross section may be adjacently disposed on the center portion of top plate 140 of casing 100G. In this case, as illustrated in FIG. 26, power supply 1G can be suspended from slide rail 11 having a T-shaped cross section disposed on an upper component of housing 10G of lamp 2G. According to power supply 1G in this variation, the area occupied by power supply 1G in lamp 2G can be decreased, similarly to power supply 1F illustrated in FIG. 24. Furthermore, according to power supply 1G in this variation, as illustrated by the arrows in FIG. 26, a flow of open air (heat flow) heated by heat dissipated from power supply 1G is smoothly caused, and thus heat dissipating capability improves similarly to the case of power supply 1F described above. This readily achieves small lamp 2G.

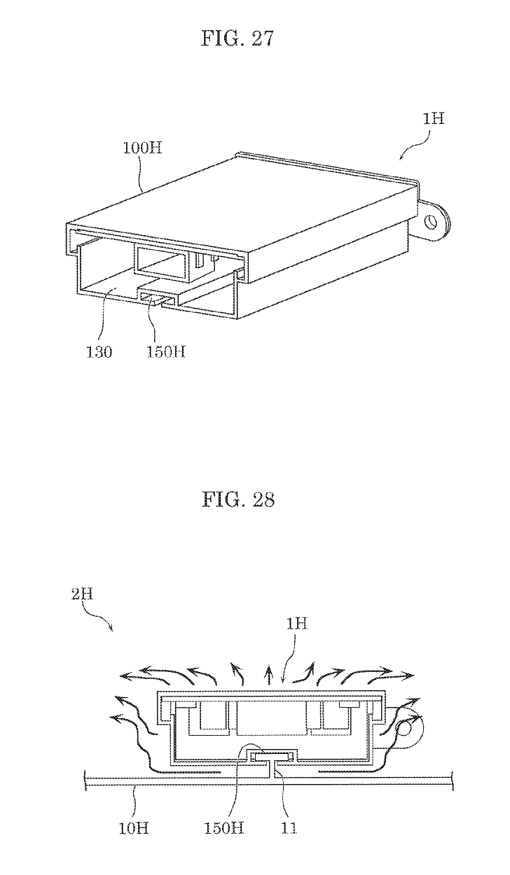

As power supply 1H illustrated in FIG. 27, guiding groove 150H which has a storing portion and in which a slit is formed may be internally provided in the center portion of bottom plate 130 of casing 100H. In this case, as illustrated in FIG. 28, power supply 1H is attached to slide rail 11 having a T-shaped cross section and disposed on a lower component of housing 10H of lamp 2H. According to power supply 1H in this variation, the area occupied by power supply 1H in lamp 2H can be decreased while maintaining good water resistance and heat dissipating capability. Furthermore, according to power supply in this variation, as illustrated by the arrows in FIG. 28, a flow of open air (heat flow) heated by heat dissipated from power supply 1H is smoothly caused, and thus heat dissipating performance improves, similarly to the case of power supply 1G described above. This readily achieves small lamp 2H. Moreover, according to this variation, the mounting structure on the lamp 2H side can be simplified. The external surface of power supply 1H includes almost no protrusions, and thus power supply 1H that can be readily handled can be achieved.

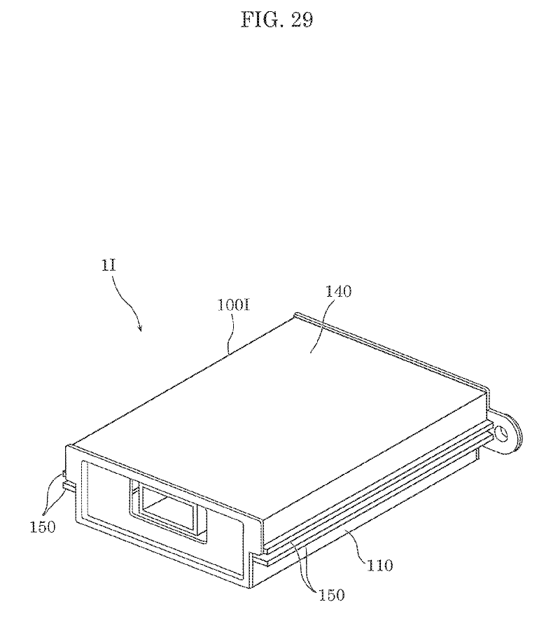

In Embodiments 1 to 3 above, guiding grooves 150 are disposed on the edge portions of first side wall 110 and second side wall 120 on the top plate 140 side, but the present disclosure is not limited thereto. For example, as casing 100I in power supply 1I illustrated in FIG. 29, guiding grooves 150 may be disposed on the center portions of first side wall 110 and second side wall 120.

Note that when guiding grooves 150 are to be disposed on first side wall 110 and second side wall 120, rather than disposing one on each of the edge portions on the bottom plate 130 side as in FIG. 1, one on each of the edge portions on the top plate 140 side as illustrated in FIG. 18, and one on each of the center portions as illustrated in FIG. 29, guiding grooves 150 may be disposed on all the three portions on each side wall or may be provided on two of the three portions on each side wall. Accordingly, one type of casing can be utilized for different types of the housing. Heat dissipating capability of the power supply can be improved by disposing guiding grooves 150 on a plurality of portions.

The present disclosure also includes embodiments as a result of adding, to the embodiments and the variations, various modifications that may be conceived by those skilled in the art, and embodiments achieved by combining elements in the embodiments and the variations in any manner without departing from the spirit of the present disclosure.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A power supply, comprising:
a casing including a heat-conducting material and having an inner surface and an outer surface, the casing being a one-piece component having a substantially tubular shape;
a circuit board disposed in the casing, the circuit board having a first surface on which one or more circuit components are mounted and a second surface on an opposing side of the first surface;
a first cover disposed over a first opening at a first end portion of the casing on a tubular axis; and
a second cover disposed over a second opening at a second end portion of the casing on the tubular axis, wherein
the first surface of the circuit board faces the inner surface of the casing.

2. The power supply according to claim 1, wherein
the outer surface of the casing accounts for at least 80% of a total outer surface area of the power supply.

3. The power supply according to claim 1, wherein
the first cover includes a first protrusion protruding inwardly towards interior of the casing,
the second cover includes a second protrusion protruding inwardly towards the interior of the casing, and
the first protrusion and the second protrusion press the circuit board against the inner surface of the casing.

4. The power supply according to claim 3, wherein
the circuit board includes a first notch and a second notch,
the first protrusion includes a first engagement portion configured to engage the first notch, and
the second protrusion includes a second engagement portion configured to engage the second notch.

5. The power supply according to claim 3, wherein
an outer edge portion of the first cover extends beyond an outer edge of the first opening by at least 0.5 mm, and
an outer edge portion of the second cover extends beyond an outer edge of the second opening by at least 0.5 mm.

6. The power supply according to claim 1, wherein
the circuit board is slidingly inserted into the casing in a sliding direction,
the casing includes:
a first side wall located at a first end portion of the casing in a direction orthogonal to the sliding direction;
a second side wall located at a second end portion of the casing in the direction orthogonal to the sliding direction;
a bottom plate having an inner surface which faces the first surface of the circuit board; and
a top plate having an inner surface which faces the second surface of the circuit board,
a first end portion of the circuit board in the direction orthogonal to the sliding direction is disposed between the top plate and a first side wall step portion provided on the first side wall, and
a second end portion of the circuit board in the direction orthogonal to the sliding direction is disposed between the top plate and a second side wall step portion provided on the second side wall.

7. The power supply according to claim 6, wherein
the first side wall includes a first rib protruding, from the first side wall step portion, towards the first surface of the circuit board, and
the second side wall includes a second rib protruding, from the second side wall step portion, towards the first surface of the circuit board.

8. The power supply according to claim 7, wherein
a spacing between the first rib and the first surface of the circuit board is in a range from 1 mm to 5 mm, and
a spacing between the second rib and the first surface of the circuit board is in a range from 1 mm to 5 mm.

9. The power supply according to claim 6, wherein
the circuit board includes a ground line disposed on the second surface of the circuit board,
the ground line being disposed in an end portion of the circuit board in the direction orthogonal to the sliding direction, and
the ground line being in contact with the top plate.

10. The power supply according to claim 9, wherein
the top plate includes a top plate step portion provided on the inner surface of the top plate in the direction orthogonal to the sliding direction, and
the ground line is in contact with the top plate step portion.

11. The power supply according to claim 6, further comprising:
a heat-conducting member disposed between the top plate and the second surface of the circuit board.

12. The power supply according to claim 11, wherein
the one or more circuit components include a heat-generating component, and
the heat-conducting member is disposed to overlap the heat-generating component in a plan view of the circuit board.

13. The power supply according to claim 11, wherein
the heat-conducting member includes a hardening adhesive resin.

14. The power supply according to claim 11, wherein
the inner surface of the top plate on which the heat-conducting member is disposed is an uneven surface.

15. The power supply according to claim 1, wherein
the casing includes one or more heat-dissipating fins,
the one or more heat-dissipating fins extend along the tubular axis, and
the one or more heat-dissipating fins are aligned in a direction crossing the tubular axis.

16. The power supply according to claim 1, wherein
the heat-conducting material included in the casing is a metallic material.

17. The power supply according to claim 16, wherein
the casing is an extruded aluminum casing.

18. A lamp, comprising;
a housing;
a light source disposed inside of the housing; and
the power supply according to claim 1, the power supply being configured to supply power to the light source, and disposed inside of the housing.

19. The lamp according to claim 18, wherein
the power supply is disposed such that the first surface of the circuit board faces vertically downward towards a bottom plate included in the casing.

20. The lamp according to claim 18, wherein
the housing includes a slide rail, and
the casing of the power supply includes a guiding groove configured to receive the slide rail.

21. The lamp according to claim 20, wherein
a space is present between a surface of the housing on which the slide rail is disposed and the casing of the power supply.

22. A movable device, comprising;
the lamp according to claim 18.

23. A method for manufacturing a power supply, the method comprising:
forming a casing having a substantially tubular shape by extruding a metallic material, the casing being formed to have a first opening and a second opening;
inserting, in a sliding manner, a circuit board into the casing via one of the first opening and the second opening of the casing, the circuit board having a first surface on which one or more circuit components are mounted and a second surface on an opposing side of the first surface;
attaching a first cover over the first opening; and
attaching a second cover over the second opening, wherein
when the circuit board is inserted into the casing, the circuit board is inserted with the first surface facing downward.
